(19) United States
(12) Patent Application Publication
(10) Pub. No.: US 2019/0157244 A1
(43) Pub. Date: May 23, 2019

(54) SEMICONDUCTOR DEVICE

(71) Applicant: Samsung Electronics Co., Ltd., Suwon-si (KR)

(72) Inventor: Min Gi Hong, Hwaseong-si (KR)

(21) Appl. No.: 16/014,533

(22) Filed: Jun. 21, 2018

(30) Foreign Application Priority Data
Nov. 20, 2017 (KR) 10-2017-0154638

(51) Int. Cl. H01L 25/065; H01L 23/538; H01L 23/367

(52) U.S. Cl. CPC H01L 25/0657; H01L 2225/06541; H01L 23/367; H01L 23/5384

(57) ABSTRACT

A semiconductor device is provided. The semiconductor device includes a substrate and a first semiconductor chip that is on the substrate. The first semiconductor chip includes a first surface facing the substrate, a second surface opposite the first surface and having a first circuit region therein, and a first TSV extending between the first surface and the second surface. An upper semiconductor chip is on the second surface of the first semiconductor chip, is electrically connected with the first semiconductor chip, includes an upper circuit region in a surface thereof facing the second surface of the first semiconductor chip, and does not have a TSV extending through an inside thereof. A thickness of the upper semiconductor chip is greater than a thickness of the first semiconductor chip.

### CLAIM OF PRIORITY

This application claims priority from Korean Patent Application No. 10-2017-0154638 filed on Nov. 20, 2017 in the Korean Intellectual Property Office, the disclosure of which is incorporated herein by reference in its entirety.

### FIELD

The present disclosure relates to semiconductor devices.

### BACKGROUND

Current trends in the electronic industry are moving toward the fabrication of light-weight, small-sized, high-speed, multi-functional, and high-performance products at an economical price. To this end, multi-chip stacked package technology or system in package technology may be used. Multi-chip stacked package technology or system in package technology typically uses through vias, such as through silicon vias (TSV).

As the number of semiconductor chips in a semiconductor package increases, heat emission generated from the semiconductor chips may become an issue. Accordingly, research for efficiently discharging heat generated in semiconductor packages may be ongoing.

### SUMMARY

One technical object to be solved by the present disclosure is to provide a semiconductor device in which a thickness of an upper semiconductor chip formed on a plurality of semiconductor chips is greater than a thickness of each of the plurality of semiconductor chips, and the upper semiconductor chip is used as a carrier wafer in the fabrication process, such that efficiency in the fabrication process of the semiconductor device can be enhanced.

According to an example embodiment of the present disclosure, there is provided a semiconductor device comprising a substrate, a first semiconductor chip which is arranged on the substrate, and comprises a first surface facing the substrate, and a second surface opposite the first surface and having a first circuit region arranged therein, and has a first conductive via extending between the first surface and the second surface, and an upper semiconductor chip which is arranged on the second surface of the first semiconductor chip to be electrically connected with the first semiconductor chip, and comprises an upper circuit region arranged in a surface facing the second surface of the first semiconductor chip, and does not have a conductive via extending through an inside thereof, wherein a thickness of the upper semiconductor chip is greater than a thickness of the first semiconductor chip.

According to an example embodiment of the present disclosure, there is provided a semiconductor device comprising a buffer semiconductor chip which has a buffer circuit region arranged in an upper surface thereof, a first semiconductor chip which is arranged on the upper surface of the buffer semiconductor chip, and comprises a first surface facing the upper surface of the buffer semiconductor chip, and a second surface opposite the first surface and having a first circuit region arranged therein, a second semiconductor chip which is arranged on the second surface of the first semiconductor chip, and comprises a third surface facing the second surface of the first semiconductor chip, and a fourth surface opposite the third surface and having a second circuit region arranged therein, a third semiconductor chip which is arranged on the fourth surface of the second semiconductor chip, and comprises a fifth surface facing the fourth surface of the second semiconductor chip, and a sixth surface opposite the fifth surface and having a third circuit region arranged therein, and an upper semiconductor chip which is arranged on the sixth surface of the third semiconductor chip, and comprises an upper circuit region arranged in a surface facing the sixth surface of the third semiconductor chip, and does not have a conductive via extending through an inside thereof, wherein a thickness of the upper semiconductor chip is greater than a thickness of the first semiconductor chip.

According to an example embodiment of the present disclosure, there is provided a semiconductor device comprising a substrate, a plurality of semiconductor chips which are sequentially stacked on the substrate, and comprise circuit regions formed in respective upper surfaces thereof, and have conductive vias extending through insides thereof, and an upper semiconductor chip which is arranged on the upper surfaces of the plurality of semiconductor chips, and comprises an upper circuit region arranged in a face facing the upper surfaces of the plurality of semiconductor chips, and does not have a conductive via extending through an inside thereof, wherein a thickness of the upper semiconductor chip is two times or more greater than a respective thickness of any one of the plurality of semiconductor chips, wherein the plurality of semiconductor chips comprise 2ⁿ-1 semiconductor chips, where n is an integer greater than or equal to 1.

Objectives that are intended to be addressed by the present disclosure are not limited to those mentioned above, and other objectives that are not mentioned above may be clearly understood to those skilled in the art based on the description provided below.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIG. 1 is a cross-sectional view provided to explain a semiconductor device according to some example embodiments of the present disclosure;

FIG. 2 to FIG. 8 are views illustrating intermediate stages of fabrication, provided to explain a method for fabricating the semiconductor device illustrated in FIG. 1;

FIG. 9 is a cross-sectional view provided to explain a semiconductor device according to some example embodiments of the present disclosure;

FIG. 10 is a cross-sectional view provided to explain a semiconductor device according to some example embodiments of the present disclosure;

FIG. 11 is a cross-sectional view provided to explain a semiconductor device according to some example embodiments of the present disclosure;

FIG. 12 to FIG. 17 are views illustrating intermediate stages of fabrication, provided to explain a method for fabricating the semiconductor device illustrated in FIG. 11;

FIG. 18 is a cross-sectional view provided to explain a semiconductor device according to some example embodiments of the present disclosure; and

FIG. 19 to FIG. 21 are views illustrating intermediate stages of fabrication, provided to explain a method for fabricating the semiconductor device illustrated in FIG. 18.

### DETAILED DESCRIPTION OF EMBODIMENTS

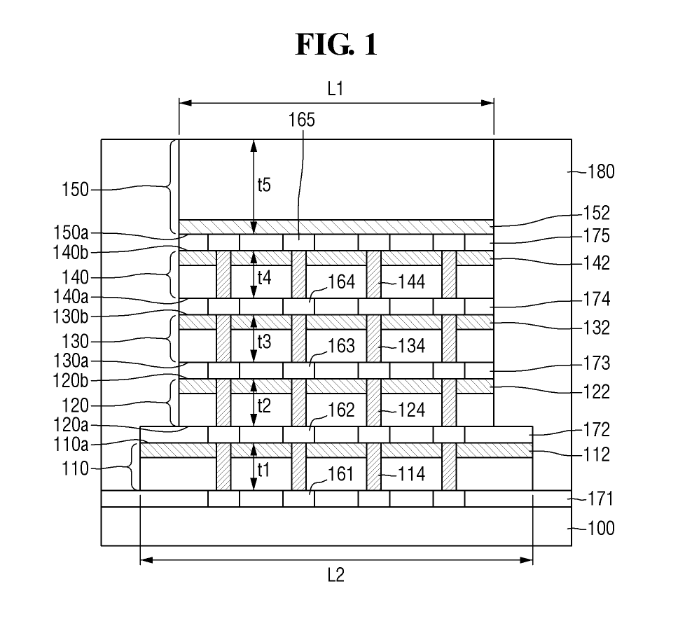

A semiconductor device according to some example embodiments will be described with reference to FIG. 1.

FIG. 1 is a cross-sectional view provided to explain a semiconductor device according to some example embodiments.

Referring to FIG. 1, the semiconductor device according to some example embodiments includes a substrate 100, a buffer semiconductor chip 110, a first semiconductor chip 120, a second semiconductor chip 130, a third semiconductor chip 140, an upper semiconductor chip 150, first to fifth connection terminals 161, 162, 163, 164, 165, first to fifth underfill materials 171, 172, 173, 174, 175, and a molding material 180. It will be understood that, although the terms first, second, third, etc. may be used herein to describe various elements, these elements should not be limited by these terms; rather, these terms are only used to distinguish one element from another element. Thus, a first element discussed below could be termed a second element without departing from the scope of the present inventive concepts. Also, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The substrate 100 may be a silicon substrate based on a semiconductor wafer. In some example embodiments, the substrate 100 may be a package substrate, and may be, for example, a printed circuit board (PCB). The substrate 100 may be electrically connected with a semiconductor chip arranged on the substrate 100.

The substrate 100 may be, for example, a bulk silicon. Alternatively, the substrate 100 may be a silicon substrate, or may include other material(s) such as silicon germanium, indium antimonide, lead telluride compound, indium arsenide, indium phosphide, gallium arsenide, or gallium antimonide. Alternatively, the substrate 100 may be a base substrate having an epitaxial layer arranged thereon.

The buffer semiconductor chip 110 may be arranged on the substrate 100. When an element is referred to herein as being “on” or “connected to” or “adjacent” another element (e.g., a layer or substrate), can be directly on or connected to or adjacent the other element, or intervening elements may also be present. In contrast, when an element is referred to as being “directly on” or “directly connected” or “immediately adjacent” another element, no intervening elements are present. The buffer semiconductor chip 110 may include a buffer circuit region 112 and a fourth through silicon via (TSV) 114.

The buffer circuit region 112 may be arranged in or adjacent an upper surface 110a of the buffer semiconductor chip 110. Specifically, the buffer circuit region 112 may be arranged in the upper surface 110a of the buffer semiconductor chip 110 which is opposite a surface of the buffer semiconductor chip 110 facing the substrate 100. In this case, the buffer circuit region 112 being arranged in the upper surface 110a of the buffer semiconductor chip 110 refers to the buffer circuit region 112 being arranged in an upper end of an inside of the buffer semiconductor chip 110, that is, towards the upper surface 110a along the thickness direction t1. The buffer circuit region 112 may include, for example, at least one transistor.

The fourth TSV 114 may be arranged to penetrate or extend the inside or thickness of the buffer semiconductor chip 110. Specifically, the fourth TSV 114 may be arranged to penetrate or extend the inside or thickness of the buffer semiconductor chip 110 in a direction perpendicular to a horizontal plane on which the substrate 100 is arranged.

Although FIG. 1 depicts that four fourth TSVs are arranged in the buffer semiconductor chip 110, this is merely for convenience of explanation, and the present disclosure is not limited thereto.

A conductive through electrode may be arranged inside the fourth TSV 114. The through electrode may include at least one of, for example, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and/or zirconium (Zr). However, embodiments of the present disclosure are not limited thereto. More generally, it will be understood that TSVs described herein may refer to any through-chip via (e.g., conductive vias formed silicon and/or materials other than silicon).

The first connection terminal 161 may be arranged between the substrate 100 and the buffer semiconductor chip 110. Specifically, the first connection terminal 161 may be arranged between (and in some embodiments, directly between) the substrate 100 and the fourth TSV 114 to provide electrical connection between the substrate 100 and the buffer semiconductor chip 110.

The first underfill material 171 may be arranged on the substrate 100. Specifically, the first underfill material 171 may be arranged between the substrate 100 and the buffer semiconductor chip 110, and may be arranged to surround the first connection terminal 161. The first underfill material 171 may bond the substrate 100 and the buffer semiconductor chip 110.

A portion of the first underfill material 171 may be exposed at a side surface or periphery of the buffer semiconductor chip 110. That is, a portion of the first underfill material 171 may be arranged to avoid overlapping the buffer semiconductor chip 110. However, embodiments of the present disclosure are not limited thereto.

The first semiconductor chip 120 may be arranged on the upper surface 110a of the buffer semiconductor chip 110. The first semiconductor chip 120 may include a first surface 120a facing the upper surface 110a of the buffer semiconductor chip 110, and a second surface 120b opposite the first surface 120a. The first semiconductor chip 120 may include a first circuit region 122 and a first TSV 124.

The first circuit region 122 may be arranged in or adjacent the second surface 120b of the first semiconductor chip 120. In this case, the first circuit region 122 being arranged in the second surface 120b of the first semiconductor chip 120 refers to the first circuit region 122 being arranged in an upper end of an inside of the first semiconductor chip 120, that is, towards the second surface 120b along the thickness direction t2. The first circuit region 122 may include, for example, at least one transistor.

The first TSV 124 may be arranged to penetrate or extend the inside or thickness of the first semiconductor chip 120. Specifically, the first TSV 124 may be arranged to penetrate between the first surface 120a of the first semiconductor chip 120 and the second surface 120b of the first semiconductor chip 120 in the direction perpendicular to the horizontal plane on which the substrate 100 is arranged.

The number/quantity of the first TSV 124 and a constitutional material thereof are similar to those of the fourth TSV 114 described above, and thus a further description thereof is omitted.

The second connection terminal 162 may be arranged between the buffer semiconductor chip 110 and the first semiconductor chip 120. Specifically, the second connection terminal 162 may be arranged between (and in some embodiments, directly between) the fourth TSV 114 and the first TSV 124 to provide electrical connection between the buffer semiconductor chip 110 and the first semiconductor chip 120.

The second underfill material 172 may be arranged on the buffer semiconductor chip 110. Specifically, the second underfill material 172 may be arranged between the buffer semiconductor chip 110 and the first semiconductor chip 120, and may be arranged to surround the second connection terminal 162. The second underfill material 172 may bond the buffer semiconductor chip 110 and the first semiconductor chip 120.

A portion of the second underfill material 172 may be exposed at a side surface or periphery of the first semiconductor chip 120. That is, a portion of the second underfill material 172 may be arranged to avoid overlapping the first semiconductor chip 120. However, embodiments of the present disclosure are not limited thereto.

The second semiconductor chip 130 may be arranged on the second surface 120b of the first semiconductor chip 120. The second semiconductor chip 130 may include a third surface 130a facing the second surface 120b of the first semiconductor chip 120, and a fourth surface 130b opposite the third surface 130a. The second semiconductor chip 130 may include a second circuit region 132 and a second TSV 134.

The second circuit region 132 may be arranged in or adjacent the fourth surface 130b of the second semiconductor chip 130. In this case, the second circuit region 132 being arranged in the fourth surface 130b of the second semiconductor chip 130 refers to the second circuit region 132 being arranged in an upper end of an inside of the second semiconductor chip 130, that is, towards the fourth surface 130b along the thickness direction t3. The second circuit region 132 may include, for example, at least one transistor.

The second TSV 134 may be arranged to penetrate or extend the inside or thickness of the second semiconductor chip 130. Specifically, the second TSV 134 may be arranged to penetrate between the third surface 130a of the second semiconductor chip 130 and the fourth surface 130b of the second semiconductor chip 130 in the direction perpendicular to the horizontal plane on which the substrate 100 is arranged.

The number/quantity of the second TSV 134 and a constitutional material thereof are similar to those of the fourth TSV 114 described above, and thus a further description thereof is omitted.

The third connection terminal 163 may be arranged between the first semiconductor chip 120 and the second semiconductor chip 130. Specifically, the third connection terminal 163 may be arranged between (and in some embodiments, directly between) the first TSV 124 and the second TSV 134 to provide electrical connection between the first semiconductor chip 120 and the second semiconductor chip 130.

The third underfill material 173 may be arranged on the first semiconductor chip 120. Specifically, the third underfill material 173 may be arranged between the first semiconductor chip 120 and the second semiconductor chip 130, and may be arranged to surround the third connection terminal 163. The third underfill material 173 may bond the first semiconductor chip 120 and the second semiconductor chip 130.

The third semiconductor chip 140 may be arranged on the fourth surface 130b of the second semiconductor chip 130. The third semiconductor chip 140 may include a fifth surface 140a facing the fourth surface 130b of the second semiconductor chip 130, and a sixth surface 140b opposite the fifth surface 140a. The third semiconductor chip 140 may include a third circuit region 142 and a third TSV 144.

The third circuit region 142 may be arranged in or adjacent the sixth surface 140b of the third semiconductor chip 140. In this case, the third circuit region 142 being arranged in the sixth surface 140b of the third semiconductor chip 140 refers to the third circuit region 142 being arranged in an upper end of an inside of the third semiconductor chip 140, that is, towards the sixth surface 140b along the thickness direction t4. The third circuit region 142 may include, for example, at least one transistor.

The third TSV 144 may be arranged to penetrate or extend the inside or thickness of the third semiconductor chip 140. Specifically, the third TSV 144 may be arranged to penetrate between the fifth surface 140a of the third semiconductor chip 140 and the sixth surface 140b of the third semiconductor chip 140 in the direction perpendicular to the horizontal plane on which the substrate 100 is arranged.

The number/quantity of the third TSV 144 and a constitutional material thereof are similar to those of the fourth TSV 114 described above, and thus a detailed description thereof is omitted.

The fourth connection terminal 164 may be arranged between the second semiconductor chip 130 and the third semiconductor chip 140. Specifically, the fourth connection terminal 164 may be arranged between (and in some embodiments, directly between) the second TSV 134 and the third TSV 144 to provide electrical connection between the second semiconductor chip 130 and the third semiconductor chip 140.

The fourth underfill material 174 may be arranged on the second semiconductor chip 130. Specifically, the fourth underfill material 174 may be arranged between the second semiconductor chip 130 and the third semiconductor chip 140, and may be arranged to surround the fourth connection terminal 164. The fourth underfill material 174 may bond the second semiconductor chip 130 and the third semiconductor chip 140.

The upper semiconductor chip 150 may be arranged on the sixth surface 140b of the third semiconductor chip 140. The upper semiconductor chip 150 may include an upper circuit region 152.

The upper circuit region 152 of the upper semiconductor chip 150 may be arranged to face the third circuit region 142 of the third semiconductor chip 140. Specifically, the upper circuit region 152 may be arranged in or adjacent a surface 150a which faces the sixth surface 140b of the third semiconductor chip 140.

In this case, the upper circuit region 152 being arranged in the surface 150a facing the sixth surface 140b of the third semiconductor chip 140 refers to the upper circuit region 152 being arranged in a lower end of an inside of the upper semiconductor chip 150, that is, towards the surface 150a along the thickness direction t5. The upper circuit region 152 may include, for example, at least one transistor.

The upper semiconductor chip 150 does not include a TSV penetrating or extending through the inside or thickness thereof. Specifically, the upper semiconductor chip 150 does not include a TSV penetrating or extending through the upper semiconductor chip 150 in the direction perpendicular to the horizontal plane on which the substrate 100 is arranged.

The fifth connection terminal 165 may be arranged between the third semiconductor chip 140 and the upper semiconductor chip 150. Specifically, the fifth connection terminal 165 may be arranged between (and in some embodiments, directly between) the third TSV 144 and the upper circuit region 152 to provide electrical connection between the third semiconductor chip 140 and the upper semiconductor chip 150.

The fifth underfill material 175 may be arranged on the third semiconductor chip 140. Specifically, the fifth underfill material 175 may be arranged between the third semiconductor chip 140 and the upper semiconductor chip 150, and may be arranged to surround the fifth connection terminal 165. The fifth underfill material 175 may bond the third semiconductor chip 140 and the upper semiconductor chip 150.

The buffer semiconductor chip 110, the first semiconductor chip 120, the second semiconductor chip 130, the third semiconductor chip 140, and the upper semiconductor chip 150 may be, for example, memory chips, logic chips, and so on.

When the buffer semiconductor chip 110, the first semiconductor chip 120, the second semiconductor chip 130, the third semiconductor chip 140 and/or the upper semiconductor chip 150 is a logic chip, the buffer semiconductor chip 110, the first semiconductor chip 120, the second semiconductor chip 130, the third semiconductor chip 140 and/or the upper semiconductor chip 150 may be designed diversely, considering an operation, etc. performed. The term “and/or” includes any and all combinations of one or more of the associated listed items.

When the buffer semiconductor chip 110, the first semiconductor chip 120, the second semiconductor chip 130, the third semiconductor chip 140 and/or the upper semiconductor chip 150 is a memory chip, the memory chip may be, for example, a non-volatile memory chip. Specifically, the memory chip may be a flash memory chip. More specifically, the memory chip may be any one of a NAND flash memory chip or a NOR flash memory chip.

However, memory devices according to embodiments of the present disclosure are not limited to the specific configuration exemplified above. According to some example embodiments, the memory chip may include any one of a phase-change random-access memory (PRAM), a magneto-resistive random-access memory (MRAM), or a resistive random-access memory (RRAM).

As described herein, a thickness refers to a thickness in the direction perpendicular to the surface of the substrate 100 on which the chips 110-150 are stacked or the horizontal plane on which the substrate 100 is arranged, and a width refers to a width on a plane parallel to the horizontal plane on which the substrate 100 is arranged.

A thickness t2 of the first semiconductor chip 120, a thickness t3 of the second semiconductor chip 130, and a thickness t4 of the third semiconductor chip 140 may be the same as (i.e., equal to) one another. That is, in some embodiments, the first, second, and third semiconductor chips 120, 130, and 140 may define a chip stack including semiconductor chips that have the same thickness, and that have respective circuit regions 122, 132, and 142 in surfaces thereof 120b, 130b, and 140b that do not face each other (e.g., a chip stack that is free of circuit regions facing one another).

A thickness t1 of the buffer semiconductor chip 110 may be the same as the thickness t2 of the first semiconductor chip 120, the thickness t3 of the second semiconductor chip 130, and the thickness t4 of the third semiconductor chip 140. However, embodiments of the present disclosure are not limited thereto. That is, in some example embodiments, the thickness t1 of the buffer semiconductor chip 110 may be different from the thickness t2 of the first semiconductor chip 120, the thickness t3 of the second semiconductor chip 130, and/or the thickness t4 of the third semiconductor chip 140.

A thickness t5 of the upper semiconductor chip 150 may be greater than the thickness t2 of the first semiconductor chip 120, the thickness t3 of the second semiconductor chip 130, and the thickness t4 of the third semiconductor chip 140. For example, the thickness t5 of the upper semiconductor chip 150 may be two times or more greater than the thickness t2 of the first semiconductor chip 120, the thickness t3 of the second semiconductor chip 130, or the thickness t4 of the third semiconductor chip 140.

A width L1 of the upper semiconductor chip 150 may be the same as a width of each of the first to third semiconductor chips 120, 130, 140. However, embodiments of the present disclosure are not limited thereto. That is, in some example embodiments, the width L1 of the upper semiconductor chip 150 may be different from the width of one or more or all of the first to third semiconductor chips 120, 130, 140 according to or depending on a fabrication method.

A width L2 of the buffer semiconductor chip 110 may be greater than the width L1 of the upper semiconductor chip 150. That is, the width L2 of the buffer semiconductor chip 110 may be greater than the width L1 of each of the first to third semiconductor chips 120, 130, 140 and the upper semiconductor chip 150. However, embodiments of the present disclosure are not limited thereto.

Although FIG. 1 depicts that the three semiconductor chips 120, 130, 140 are arranged between the buffer semiconductor chip 110 and the upper semiconductor chip 150, this is merely an example, and the present disclosure is not limited thereto.

That is, in some example embodiments, 2ⁿ-1 (n is an integer greater than or equal to 1) number of semiconductor chips may be arranged between the buffer semiconductor chip 110 and the upper semiconductor chip 150. In this case, each of the plurality of semiconductor chips may have the same thickness and width. However, embodiments of the present disclosure are not limited thereto.

The molding material 180 may be arranged on the substrate 100. Specifically, the molding material 180 may be arranged to cover the first to fifth underfill materials 171, 172, 173, 174, 175, the side surfaces of the buffer semiconductor chip 110, the side surfaces of the first semiconductor chip 120, the side surfaces of the second semiconductor chip 130, the side surfaces of the third semiconductor chip 140, and the side surfaces of the upper semiconductor chip 150, which are exposed.

An upper surface of the molding material 180 may be coplanar with the upper surface of the upper semiconductor chip 150. However, embodiments of the present disclosure are not limited thereto.

The molding material 180 may include, for example, an epoxy molding compound (EMC), or two or more kinds of silicon hybrid materials.

In the semiconductor device according to some example embodiments, the thickness t5 of the upper semiconductor chip 150 is greater than the respective thicknesses t2, t3, t4 of the first to third semiconductor chips 120, 130, 140, such that a separate carrier wafer is not required in the fabrication process of the semiconductor device, and the upper semiconductor chip 150 can be used as a carrier wafer.

To this end, a separate process for bonding and de-bonding the carrier wafer is removed or eliminated from the fabrication process for fabricating the semiconductor device according to some example embodiments, such that the fabrication process of the semiconductor device can be simplified, and a fabrication cost can be reduced.

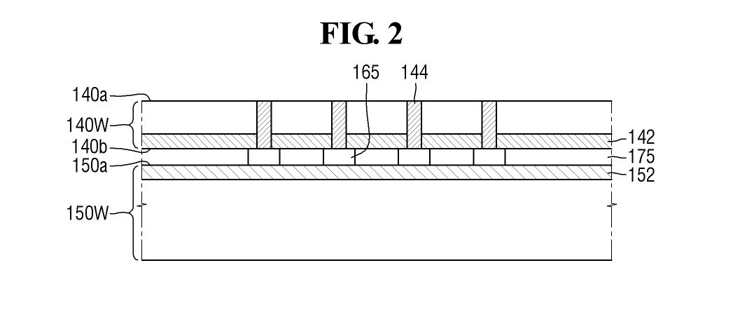

A method for fabricating a semiconductor device according to some example embodiments will be described with reference to FIG. 2 to FIG. 8.

FIG. 2 to FIG. 8 are views illustrating intermediate stages of fabrication, provided to explain a method for fabricating the semiconductor device illustrated in FIG. 1.

Referring to FIG. 2, an upper semiconductor wafer 150W having an upper circuit region 152 formed in the upper surface 150a thereof may be provided. In addition, a third semiconductor wafer 140W having the third circuit region 142 formed in the sixth surface 140b thereof, and the third TSV 144 penetrating or extending through the inside or thickness thereof may be provided.

The third semiconductor wafer 140W may be formed on the upper surface 150a of the upper semiconductor wafer 150W, such that the upper surface 150a of the upper semiconductor wafer 150W and the sixth surface 140b of the third semiconductor wafer 140W face each other. Accordingly, the upper circuit region 152 and the third circuit region 142 may be formed to face each other.

The fifth connection terminal 165 and the fifth underfill material 175 formed to surround the fifth connection terminal 165 may be formed between the upper semiconductor wafer 150W and the third semiconductor wafer 140W.

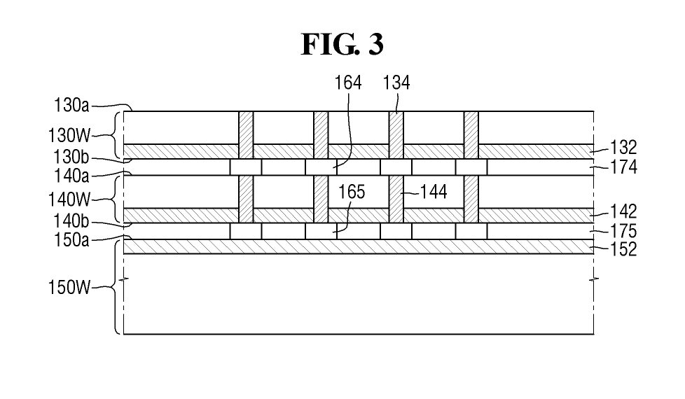

Referring to FIG. 3, a second semiconductor wafer 130W having the second circuit region 132 formed in the fourth surface 130b thereof, and the second TSV 134 penetrating or extending through the inside or thickness thereof may be provided.

The second semiconductor wafer 130W may be formed on the fifth surface 140a opposite the sixth surface 140b of the third semiconductor wafer 140W, such that the fifth surface 140a of the third semiconductor wafer 140W and the fourth surface 130b of the second semiconductor wafer 130W face each other.

The fourth connection terminal 164 and the fourth underfill material 174 formed to surround the fourth connection terminal 164 may be formed between the third semiconductor wafer 140W and the second semiconductor wafer 130W.

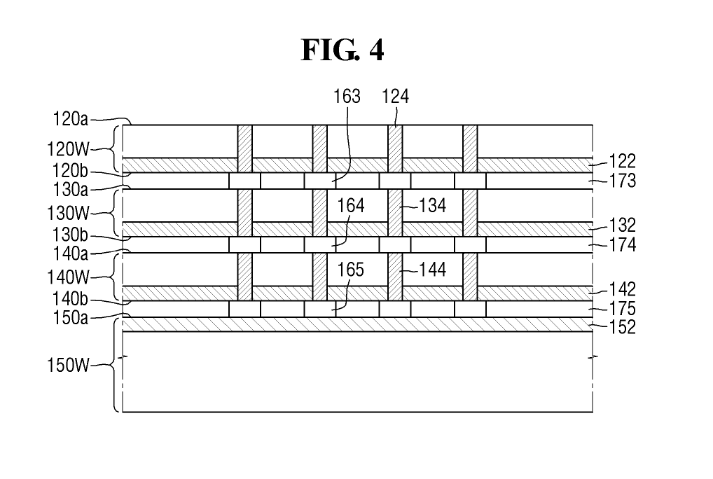

Referring to FIG. 4, a first semiconductor wafer 120W having the first circuit region 122 formed in the second surface 120b thereof, and the first TSV 124 penetrating or extending through the inside or thickness thereof may be provided.

The first semiconductor wafer 120W may be formed on the third surface 130a opposite the fourth surface 130b of the second semiconductor wafer 130W, such that the third surface 130a of the second semiconductor wafer 130W and the second surface 120b of the first semiconductor wafer 120W face each other.

The third connection terminal 163 and the third underfill material 173 formed to surround the third connection terminal 163 may be formed between the second semiconductor wafer 130W and the first semiconductor wafer 120W.

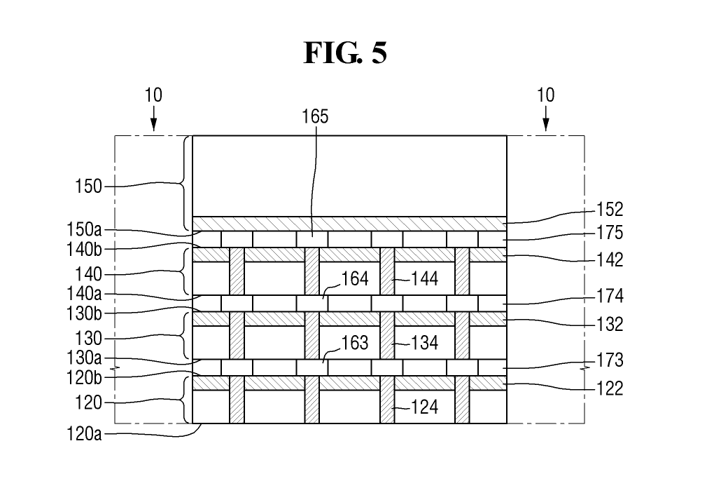

Referring to FIG. 5, the semiconductor device may be inverted such that the first semiconductor wafer 120W is positioned on the lower portion, and the upper semiconductor wafer 150W is positioned on the upper portion. The first to third semiconductor wafers 120W, 130W, 140W and the upper semiconductor wafer 150W may be cut through a first dicing process 10.

Through this process, a structure may be formed, wherein the first semiconductor chip 120, the second semiconductor chip 130, the third semiconductor chip 140, and the upper semiconductor chip 150 are stacked in sequence.

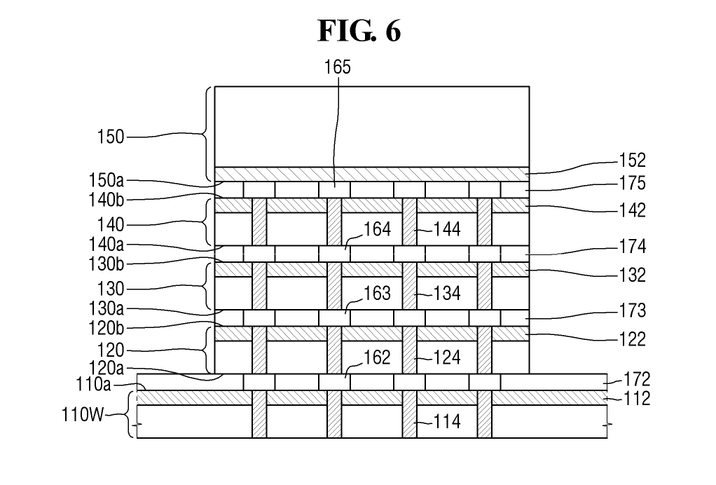

Referring to FIG. 6, a buffer semiconductor wafer 110W having the buffer circuit region 112 formed in the upper surface 110a thereof, and the fourth TSV 114 penetrating or extending through the inside or thickness thereof may be provided.

A structure may be formed, wherein the first semiconductor chip 120, the second semiconductor chip 130, the third semiconductor chip 140, and the upper semiconductor chip 150 are stacked in sequence on the upper surface 110a of the buffer semiconductor wafer 110W, such that the upper surface 110a of the buffer semiconductor wafer 110W and the first surface 120a of the first semiconductor chip 120 face each other.

The second connection terminal 162 and the second underfill material 172 formed to surround the second connection terminal 162 may be formed between the buffer semiconductor wafer 110W and the first semiconductor wafer 120W. A portion of the second underfill material 172 may be exposed at the side surface of the first semiconductor chip 120.

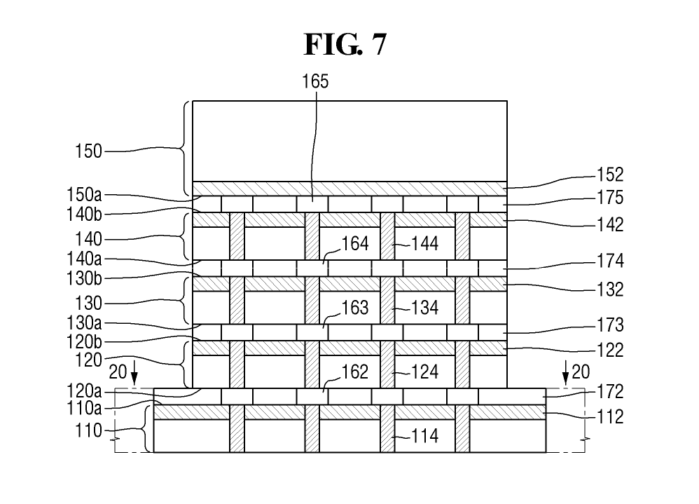

Referring to FIG. 7, the buffer semiconductor wafer 110W may be cut through a second dicing process 20. Through this process, a structure may be formed, wherein the buffer semiconductor chip 110, the first semiconductor chip 120, the second semiconductor chip 130, the third semiconductor chip 140, and the upper semiconductor chip 150 are stacked in sequence.

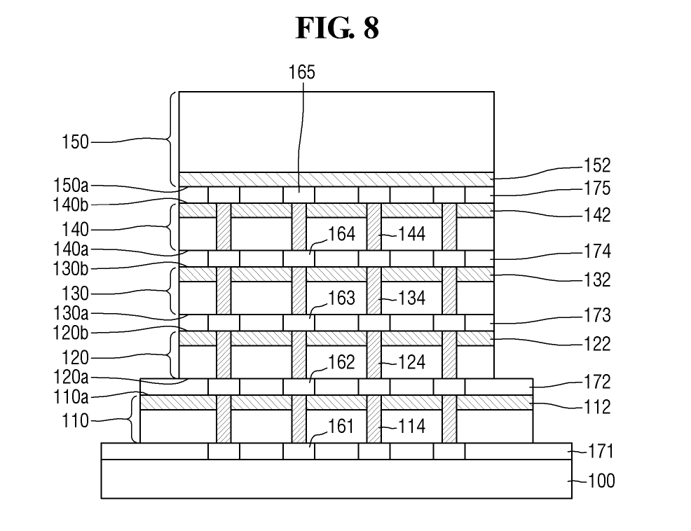

Referring to FIG. 8, a structure may be formed, wherein the buffer semiconductor chip 110, the first semiconductor chip 120, the second semiconductor chip 130, the third semiconductor chip 140, and the upper semiconductor chip 150 are stacked in sequence on the substrate 100.

The first connection terminal 161 and the first underfill material 171 formed to surround the first connection terminal 161 may be formed between the substrate 100 and the buffer semiconductor chip 110. A portion of the first underfill material 171 may be exposed at the side surface of the buffer semiconductor chip 110.

The molding material 180 may be formed to cover the first to fifth underfill materials 171, 172, 173, 174, 175, the side surfaces of the buffer semiconductor chip 110, the side surfaces of the first semiconductor chip 120, the side surfaces of the second semiconductor chip 130, the side surfaces of the third semiconductor chip 140, and the side surfaces of the upper semiconductor chip 150, which are exposed. Through the above-described process, the semiconductor device illustrated in FIG. 1 may be fabricated.

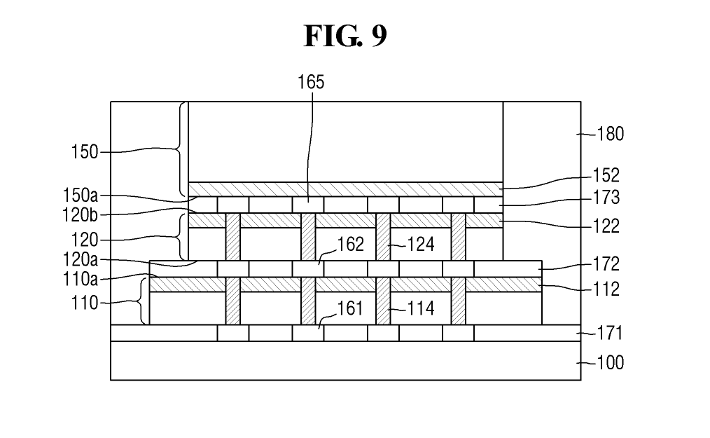

A semiconductor device according to some example embodiments will be described with reference to FIG. 9. Differences from the semiconductor device illustrated in FIG. 1 will be primarily described.

FIG. 9 is a cross-sectional view provided to explain a semiconductor device according to some example embodiments.

Referring to FIG. 9, the semiconductor device according to some example embodiments may have one semiconductor chip arranged between the buffer semiconductor chip 110 and the upper semiconductor chip 150.

Specifically, the first semiconductor chip 120 may be arranged between the buffer semiconductor chip 110 and the upper semiconductor chip 150, such that the upper circuit region 152 arranged in the lower surface 150a of the upper semiconductor chip 150, and the first circuit region 122 arranged in the second surface 120b of the first semiconductor chip 120 face each other.

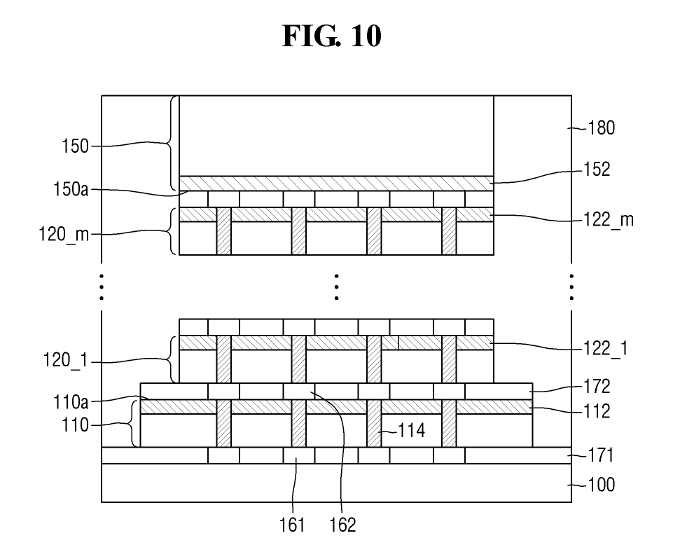

A semiconductor device according to some example embodiments will be described with reference to FIG. 10. Differences from the semiconductor device illustrated in FIG. 1 will be primarily described.

FIG. 10 is a cross-sectional view provided to explain a semiconductor device according to some example embodiments.

Referring to FIG. 10, the semiconductor device according to some example embodiments may have a plurality of semiconductor chips arranged between the buffer semiconductor chip 110 and the upper semiconductor chip 150.

Specifically, m number of semiconductor chips (m=2ⁿ-1, n is an integer greater than or equal to 1), that is, the first semiconductor chip 120_1 to m-th semiconductor chip 120_m, may be arranged between the buffer semiconductor chip 110 and the upper semiconductor chip 150.

Each of the first circuit region 122_1 of the first semiconductor chip 120_1 to the m-th circuit region 122_m of the m-th semiconductor chip 120_m may be arranged to face the upper circuit region 152 of the upper semiconductor chip 150.

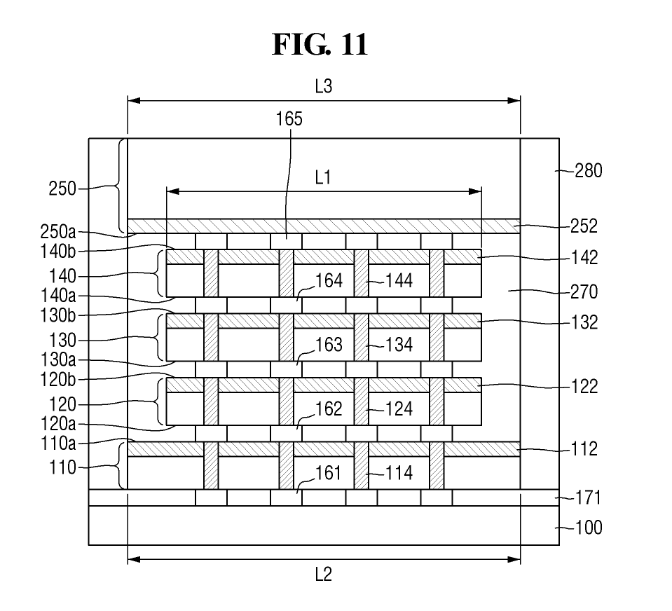

A semiconductor device according to some example embodiments will be described with reference to FIG. 11. Differences from the semiconductor device illustrated in FIG. 1 will be primarily described.

FIG. 11 is a cross-sectional view provided to explain a semiconductor device according to some example embodiments.

Referring to FIG. 11, in the semiconductor device according to some example embodiments, a width L3 of an upper semiconductor chip 250 may be greater than the width L1 of each of the first to third semiconductor chips 120, 130, 140. Accordingly, a portion of an edge of an upper circuit region 252 arranged in a lower surface 250a of the upper semiconductor chip 250 may not completely overlap each of the first to third semiconductor chips 120, 130, 140.

In addition, the width L3 of the upper semiconductor chip 250 may be the same as the width L2 of the buffer semiconductor chip 110.

A second underfill material 270 may be arranged to cover the side surfaces of the first semiconductor chip 120, the side surfaces of the second semiconductor chip 130, and the side surfaces of the third semiconductor chip 140. A side surface of the second underfill material 270 may be coplanar with the side surface of the upper semiconductor chip 250 and the side surface of the buffer semiconductor chip 110.

A molding material 280 may be arranged to cover the first underfill material 171, the side surfaces of the buffer semiconductor chip 110, the side surfaces of the second underfill material 270, and the side surfaces of the upper semiconductor chip 250, which are exposed.

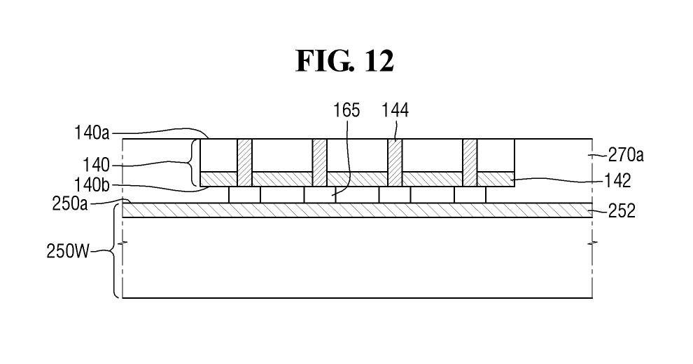

A method for fabricating a semiconductor device according to some example embodiments will be described with reference to FIG. 12 to FIG. 17.

FIG. 12 to FIG. 17 are views illustrating intermediate stages of fabrication, provided to explain a method for fabricating the semiconductor device shown in FIG. 11.

Referring to FIG. 12, an upper semiconductor wafer 250W having the upper circuit region 252 formed in the upper surface 250a thereof may be provided. In addition, the third semiconductor chip 140 having the third circuit region 142 formed in the sixth surface 140b thereof, and the third TSV 144 penetrating or extending through the inside or thickness thereof may be provided.

The third semiconductor chip 140 may be formed on the upper surface 250a of the upper semiconductor wafer 250W, such that the upper surface 250a of the upper semiconductor wafer 250W and the sixth surface 140b of the third semiconductor chip 140 face each other. Accordingly, the upper circuit region 252 and the third circuit region 142 may be formed to face each other.

The fifth connection terminal 165 and a third underfill material 270a formed to surround the fifth connection terminal 165 may be formed between the upper semiconductor wafer 250W and the third semiconductor chip 140. The third underfill material 270a may be formed to surround the side surfaces of the third semiconductor chip 140.

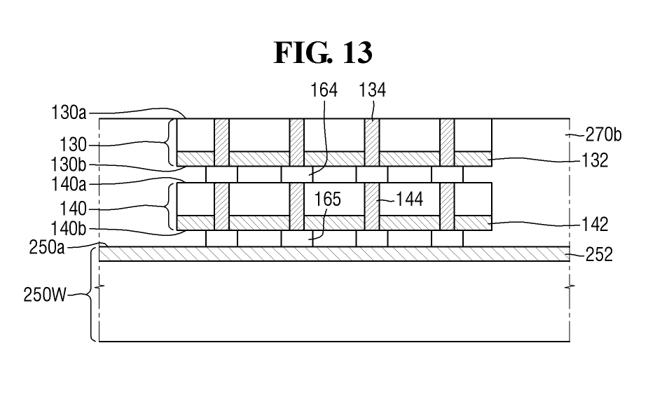

Referring to FIG. 13, the second semiconductor chip 130 having the second circuit region 132 formed in the fourth surface 130b thereof, and the second TSV 134 penetrating or extending through the inside or thickness thereof may be provided.

The second semiconductor chip 130 may be formed on the fifth surface 140a of the third semiconductor chip 140, such that the fifth surface 140a of the third semiconductor chip 140 and the fourth surface 130b of the second semiconductor chip 130 face each other.

The fourth connection terminal 164 may be formed between the third semiconductor chip 140 and the second semiconductor chip 130. A fourth underfill material 270b illustrated in FIG. 13 is illustrated as including the third underfill material 270a illustrated in FIG. 12. The fourth underfill material 270b may be formed to additionally surround the fourth connection terminal 164 and the side surfaces of the second semiconductor chip 130.

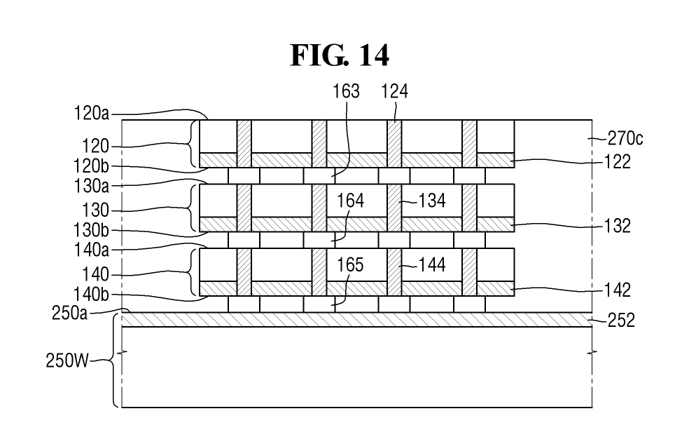

Referring to FIG. 14, the first semiconductor chip 120 having the first circuit region 122 formed in the second surface 120b thereof, and the first TSV 124 penetrating or extending through the inside or thickness thereof may be provided.

The first semiconductor chip 120 may be formed on the third surface 130a of the second semiconductor chip 130, such that the third surface 130a of the second semiconductor chip 130 and the second surface 120b of the first semiconductor chip 120 face each other.

The third connection terminal 163 may be formed between the second semiconductor chip 130 and the first semiconductor chip 120. A fifth underfill material 270c illustrated in FIG. 14 is illustrated as including the fourth underfill material 270b illustrated in FIG. 13. The fifth underfill material 270c may be formed to additionally surround the third connection terminal 163 and the side surfaces of the first semiconductor chip 120.

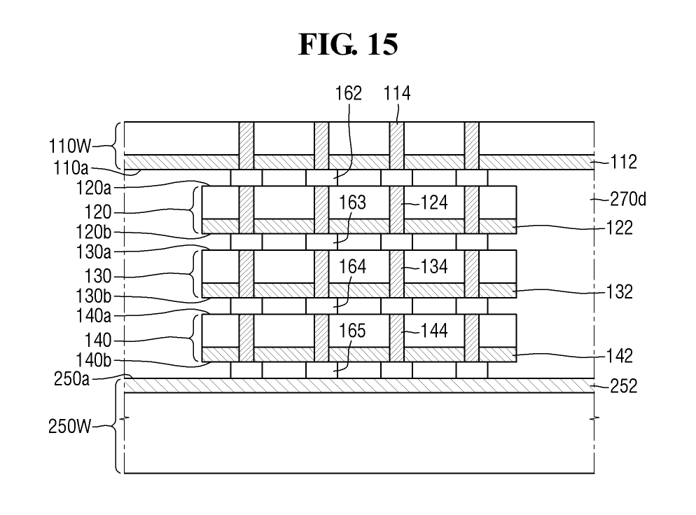

Referring to FIG. 15, the buffer semiconductor wafer 110W having the buffer circuit region 112 formed in the lower surface 110a thereof facing the first surface 120a of the first semiconductor chip 120, and the fourth TSV 114 penetrating or extending through the inside or thickness thereof may be provided.

The buffer semiconductor wafer 110W may be formed on the first surface 120a of the first semiconductor chip 120, such that the first surface 120a of the first semiconductor chip 120 and the lower surface 110a of the buffer semiconductor wafer 110W face each other.

The second connection terminal 162 may be formed between the first semiconductor chip 120 and the buffer semiconductor wafer 110W. A sixth underfill material 270d illustrated in FIG. 15 is illustrated as including the fifth underfill material 270c illustrated in FIG. 14. The sixth underfill material 270d may be formed to additionally surround the side surfaces of the second connection terminal 162.

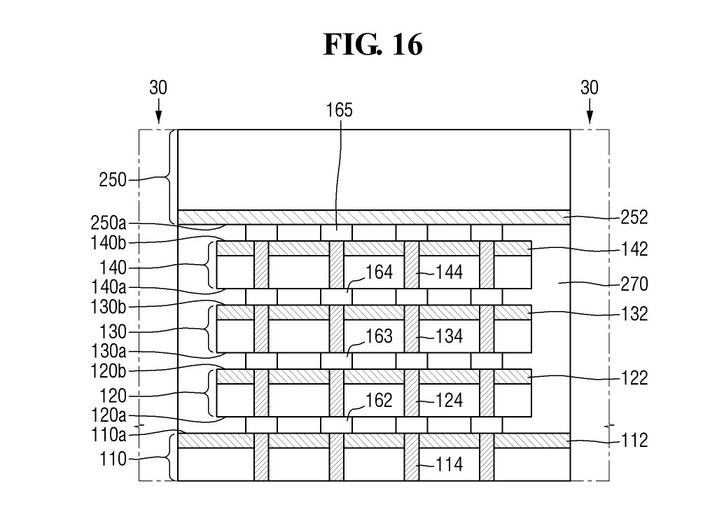

Referring to FIG. 16, the semiconductor device may be inverted such that the buffer semiconductor wafer 110W is positioned on the lower portion, and the upper semiconductor wafer 250W is positioned on the upper portion. The buffer semiconductor wafer 110W and the upper semiconductor wafer 250W may be cut through a third dicing process 30.

Through this process, a structure may be formed, wherein the buffer semiconductor chip 110, the first semiconductor chip 120, the second semiconductor chip 130, the third semiconductor chip 140, and the upper semiconductor chip 250 are stacked in sequence. A width (L2 of FIG. 11) of the buffer semiconductor chip 110 may be the same as a width (L3 of FIG. 11) of the upper semiconductor chip 250.

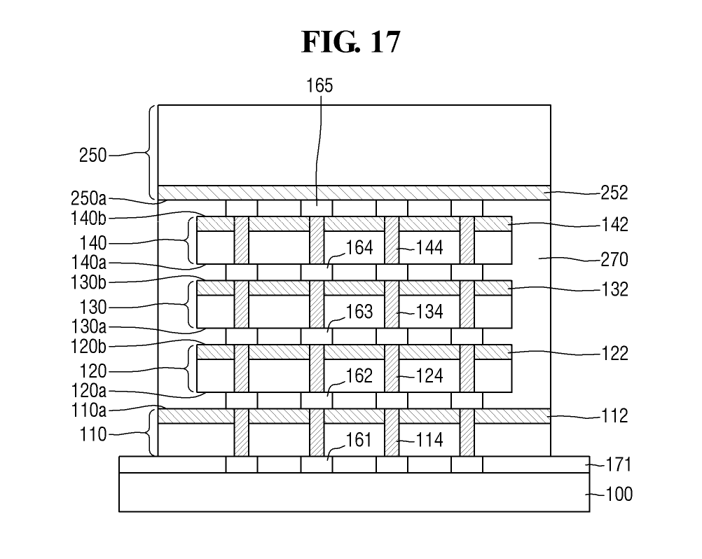

Referring to FIG. 17, a structure may be formed, wherein the buffer semiconductor chip 110, the first semiconductor chip 120, the second semiconductor chip 130, the third semiconductor chip 140, and the upper semiconductor chip 250 are stacked in sequence on the substrate 100.

The first connection terminal 161 and the first underfill material 171 formed to surround the first connection terminal 161 may be formed between the substrate 100 and the buffer semiconductor chip 110. A portion of the first underfill material 171 may be exposed at the side surface of the buffer semiconductor chip 110.

A molding material (280 of FIG. 11) may be formed to cover the first underfill material 171, the side surfaces of the buffer semiconductor chip 110, the side surfaces of the second underfill material 270, and the side surfaces of the upper semiconductor chip 250, which are exposed. Through the above-described process, the semiconductor device illustrated in FIG. 11 may be fabricated.

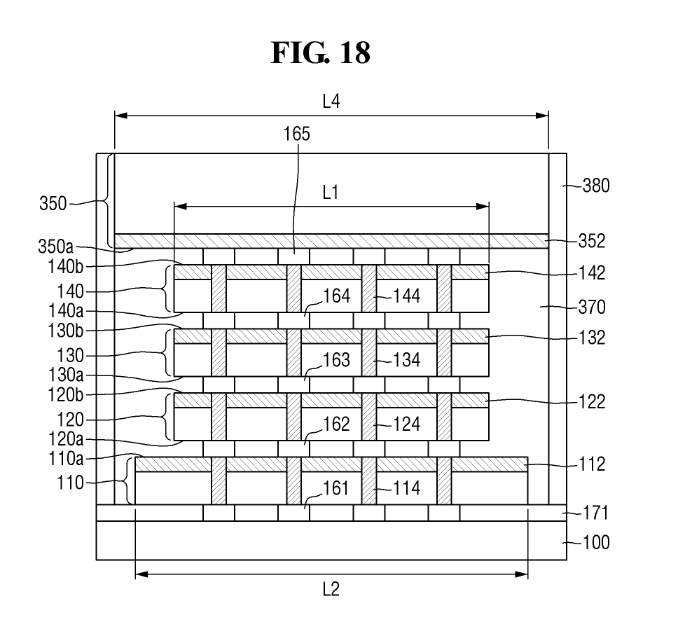

A semiconductor device according to some example embodiments will be described with reference to FIG. 18. Differences from the semiconductor device illustrated in FIG. 1 will be primarily described.

FIG. 18 is a cross-sectional view provided to explain a semiconductor device according to some example embodiments.

Referring to FIG. 18, in the semiconductor device according to some example embodiments, a width L4 of an upper semiconductor chip 350 may be greater than the width L2 of the buffer semiconductor chip 110. To this end, a portion of an edge of an upper circuit region 352 arranged in a lower surface 350a of the upper semiconductor chip 350 may not completely overlap the buffer semiconductor chip 110.

A second underfill material 370 may be arranged to cover the side surfaces of the buffer semiconductor chip 110, the side surfaces of the first semiconductor chip 120, the side surfaces of the second semiconductor chip 130, and the side surfaces of the third semiconductor chip 140. A side surface of the second underfill material 370 may be coplanar with the side surface of the upper semiconductor chip 350.

A molding material 380 may be arranged to cover the first underfill material 171, the side surfaces of the second underfill material 370, and the side surfaces of the upper semiconductor chip 350, which are exposed.

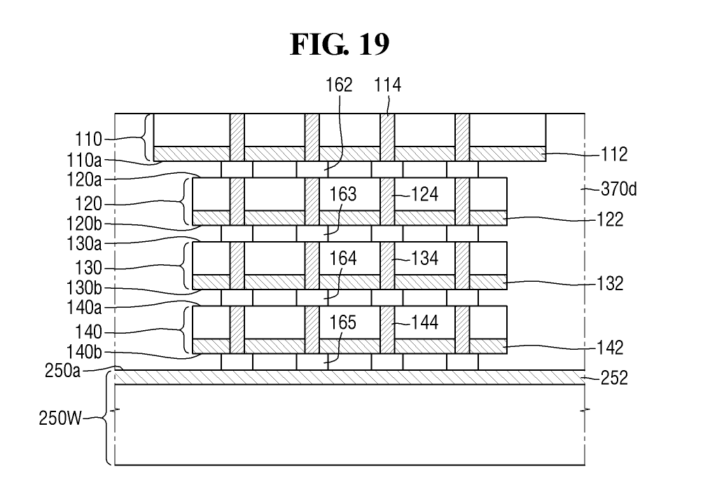

A method for fabricating a semiconductor device according to some example embodiments will be described with reference to FIG. 19 to FIG. 21. Differences from the method for fabricating the semiconductor device illustrated in FIG. 2 to FIG. 8 will be primarily described. Differences from the method for fabricating the semiconductor device illustrated in FIG. 12 to FIG. 17 will be primarily described.

FIG. 19 to FIG. 21 are views illustrating intermediate stages of fabrication, provided to explain a method for fabricating the semiconductor device illustrated in FIG. 18. FIG. 19 illustrates a process after the fabrication process of the semiconductor device illustrated in FIG. 12 to FIG. 14.

Referring to FIG. 19, the buffer semiconductor chip 110 having the buffer circuit region 112 formed in the lower surface 110a thereof facing the first surface 120a of the first semiconductor chip 120, and the fourth TSV 114 penetrating or extending through the inside or thickness thereof may be provided. A width (L2 of FIG. 18) of the buffer semiconductor chip 110 may be greater than a width (L1 of FIG. 18) of each of the first to third semiconductor chips 120, 130, 140.

The buffer semiconductor chip 110 may be formed on the first surface 120a of the first semiconductor chip 120, such that the first surface 120a of the first semiconductor chip 120 and the lower surface 110a of the buffer semiconductor chip 110 face each other.

The second connection terminal 162 may be formed between the first semiconductor chip 120 and the buffer semiconductor chip 110. A sixth underfill material 370d illustrated in FIG. 19 is illustrated as including the fifth underfill material 270c illustrated in FIG. 14. The sixth underfill material 370d may be formed to additionally surround the side surfaces of the second connection terminal 162 and the side surfaces of the buffer semiconductor chip 110.

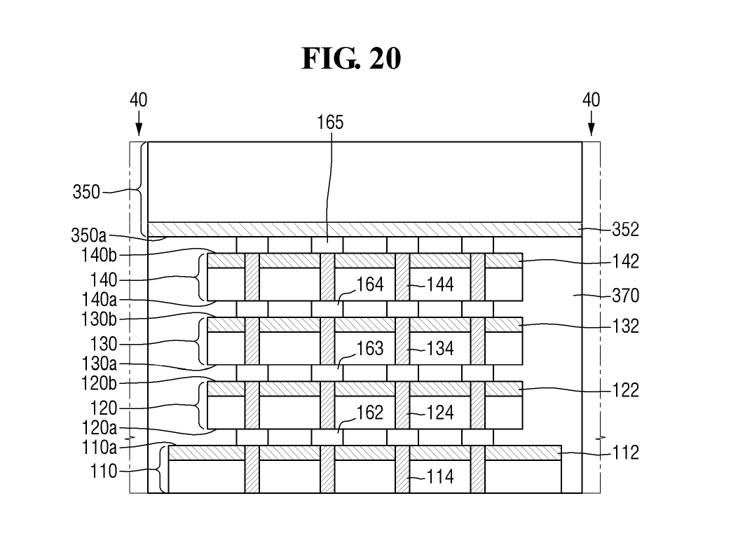

Referring to FIG. 20, the semiconductor device may be inverted such that the buffer semiconductor chip 110 is positioned on the lower portion, and the upper semiconductor wafer 250W is positioned on the upper portion. The upper semiconductor wafer 250W may be cut through a fourth dicing process 40.

Through this process, a structure may be formed, wherein the buffer semiconductor chip 110, the first semiconductor chip 120, the second semiconductor chip 130, the third semiconductor chip 140, and the upper semiconductor chip 350 are stacked in sequence. A width (L4 of FIG. 18) of the upper semiconductor chip 350 may be greater than the width (L2 of FIG. 18) of the buffer semiconductor chip 110.

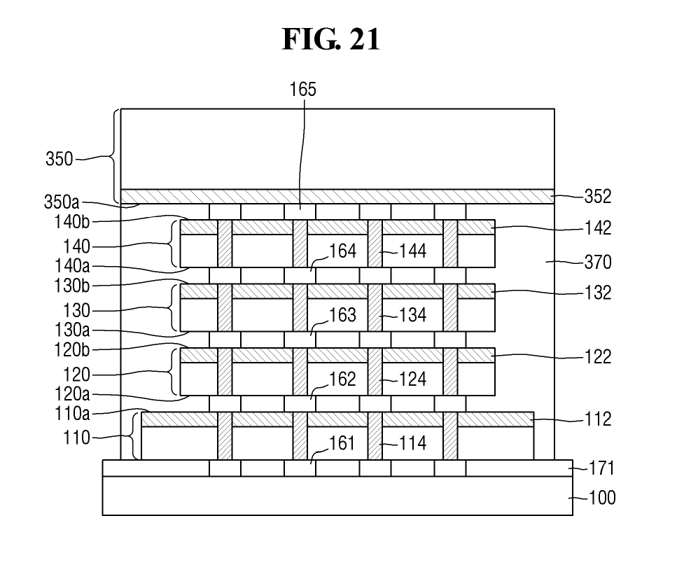

Referring to FIG. 21, a structure may be formed, wherein the buffer semiconductor chip 110, the first semiconductor chip 120, the second semiconductor chip 130, the third semiconductor chip 140, and the upper semiconductor chip 350 are stacked in sequence on the substrate 100.

The first connection terminal 161 and the first underfill material 171 formed to surround the first connection terminal 161 may be formed between the substrate 100 and the buffer semiconductor chip 110. A portion of the first underfill material 171 may be exposed at the side surface of the second underfill material 370.

a molding material (380 of FIG. 18) may be formed to cover the first underfill material 171, the side surfaces of the second underfill material 370, and the side surfaces of the upper semiconductor chip 350, which are exposed. Through the above-described process, the semiconductor device illustrated in FIG. 18 may be fabricated.

Example embodiments according to the present disclosure were explained hereinabove with reference to the drawings attached, but it should be understood that the present disclosure is not limited to the aforementioned example embodiments, but may be fabricated in various different forms, and may be implemented by a person skilled in the art in other specific forms without altering the technical concept characteristics of the present disclosure. Accordingly, it will be understood that the example embodiments described above are only illustrative, and should not be construed as limiting.

What is claimed is:

1. A semiconductor device, comprising:
a substrate;
a first semiconductor chip that is on the substrate, wherein the first semiconductor chip comprises a first surface facing the substrate, a second surface opposite the first surface and having a first circuit region therein, and a first conductive via extending between the first surface and the second surface; and
an upper semiconductor chip that is on the second surface of the first semiconductor chip and is electrically connected with the first semiconductor chip, wherein the upper semiconductor chip comprises an upper circuit region in a surface thereof facing the second surface of the first semiconductor chip, and wherein the upper semiconductor chip is free of a conductive via extending therethrough,
wherein a thickness of the upper semiconductor chip is greater than a first thickness of the first semiconductor chip.

2. The semiconductor device of claim 1, further comprising:
a second semiconductor chip that is between the first semiconductor chip and the upper semiconductor chip, and has a second thickness that is a same thickness as the first thickness of the first semiconductor chip; and
a third semiconductor chip that is between the second semiconductor chip and the upper semiconductor chip, and has a third thickness that is the same thickness as the first thickness of the first semiconductor chip.

3. The semiconductor device of claim 2, wherein the second semiconductor chip comprises a third surface facing the first semiconductor chip, and a fourth surface opposite the third surface and having a second circuit region therein, and
wherein the third semiconductor chip comprises a fifth surface facing the second semiconductor chip, and a sixth surface opposite the fifth surface and having a third circuit region therein,
wherein the first, second, and third semiconductor chips define a chip stack comprising semiconductor chips of the same thickness and free of circuit regions that face one another.

4. The semiconductor device of claim 3, further comprising:
a second conductive via extending between the third surface of the second semiconductor chip and the fourth surface of the second semiconductor chip; and
a third conductive via extending between the fifth surface of the third semiconductor chip and the sixth surface of the third semiconductor chip,
wherein the second conductive via and the third conductive via are directly on a connection terminal that is arranged between the fourth surface of the second semiconductor chip and the fifth surface of the third semiconductor chip.

5. The semiconductor device of claim 1, wherein the thickness of the upper semiconductor chip is greater than the first thickness of the first semiconductor chip by two times or more.

6. The semiconductor device of claim 1, wherein a width of the upper semiconductor chip is greater than a width of the first semiconductor chip.

7. The semiconductor device of claim 1, further comprising:
a buffer semiconductor chip that is between the substrate and the first semiconductor chip, and has a width greater than a width of the first semiconductor chip.

8. The semiconductor device of claim 7, wherein the buffer semiconductor chip comprises:
a buffer circuit region in a surface of the buffer semiconductor chip facing the first surface of the first semiconductor chip; and
a fourth conductive via extending through the buffer semiconductor chip.

9. The semiconductor device of claim 7, wherein a thickness of the buffer semiconductor chip is the same as the first thickness of the first semiconductor chip.

10. A semiconductor device, comprising:
a buffer semiconductor chip comprising a buffer circuit region in an upper surface thereof;
a first semiconductor chip that is on the upper surface of the buffer semiconductor chip, and comprises a first surface facing the upper surface of the buffer semiconductor chip, and a second surface opposite the first surface and comprising a first circuit region therein;
a second semiconductor chip that is on the second surface of the first semiconductor chip, and comprises a third surface facing the second surface of the first semiconductor chip, and a fourth surface opposite the third surface and comprising a second circuit region therein;
a third semiconductor chip that is on the fourth surface of the second semiconductor chip, and comprises a fifth surface facing the fourth surface of the second semiconductor chip, and a sixth surface opposite the fifth surface and comprising a third circuit region therein; and
an upper semiconductor chip that is on the sixth surface of the third semiconductor chip, and comprises an upper circuit region in a surface thereof facing the sixth surface of the third semiconductor chip, and is free of a conductive via penetrating therethrough,
wherein a thickness of the upper semiconductor chip is greater than a thickness of the first semiconductor chip.

11. The semiconductor device of claim 10, wherein each of the buffer semiconductor chip, the first semiconductor chip, the second semiconductor chip, and the third semiconductor chip comprises a respective conductive via extending therethrough, and wherein the first, second, and third semiconductor chips define a chip stack comprising semiconductor chips of a same thickness and free of circuit regions that face one another.

12. The semiconductor device of claim 10, wherein the thickness of the upper semiconductor chip is greater than the thickness of the first semiconductor chip by two times or more.

13. The semiconductor device of claim 10, wherein a width of the upper semiconductor chip is greater than respective widths of the first, second, and third semiconductor chips.

14. The semiconductor device of claim 13, wherein the width of the upper semiconductor chip is the same as a width of the buffer semiconductor chip.

15. The semiconductor device of claim 10, wherein a width of the upper semiconductor chip is greater than a width of the buffer semiconductor chip.

16. A semiconductor device, comprising:
a substrate;
a plurality of semiconductor chips that are sequentially stacked on the substrate, wherein the plurality of semiconductor chips comprise circuit regions in respective upper surfaces thereof, and have conductive vias penetrating through respective thicknesses thereof; and
an upper semiconductor chip that is on the upper surfaces of the plurality of semiconductor chips, wherein the upper semiconductor chip comprises an upper circuit region facing the upper surfaces of the plurality of semiconductor chips, and is free of a conductive via penetrating therethrough,
wherein a thickness of the upper semiconductor chip is greater than a respective thickness of any one of the plurality of semiconductor chips by two times or more,
wherein the plurality of semiconductor chips comprise 2ⁿ-1 semiconductor chips, where n is an integer greater than or equal to 1.

17. The semiconductor device of claim 16, wherein the respective thicknesses of the plurality of semiconductor chips are equal, and wherein the plurality of semiconductor chips define a chip stack that is free of circuit regions that face one another.

18. The semiconductor device of claim 16, further comprising a buffer semiconductor chip that is between the substrate and the plurality of semiconductor chips, and has a width that is greater than respective widths of the plurality of semiconductor chips.

19. The semiconductor device of claim 18, wherein a thickness of the buffer semiconductor chip is equal to the respective thicknesses of the plurality of semiconductor chips.

20. The semiconductor device of claim 16, wherein a width of the upper semiconductor chip is greater than respective widths of the plurality of semiconductor chips.
